(19) United States
(12) Patent Application Publication
(10) Pub. No.: US 2024/0071720 A1
(43) Pub. Date: Feb. 29, 2024

(54) METHOD AND SYSTEM FOR PREPARING A SPECIMEN

(71) Applicant: FEI Company, Hillsboro, OR (US)

(72) Inventors: Jamie Dee Gravell, Beaverton, OR (US); Brian Roberts Routh, Beaverton, OR (US); Aurelien Philippe Jean Maclou Botman, Hillsboro, OR (US); Subhei Shaar, Redmond, WA (US)

(73) Assignee: FEI Company, Hillsboro, OR (US)

(21) Appl. No.: 18/448,430

(22) Filed: Aug. 11, 2023

Related U.S. Application Data
(60) Provisional application No. 63/397,749, filed on Aug. 12, 2022.

(51) Int. Cl. H01J 37/317; H01J 37/20; H01J 37/305

(52) U.S. Cl. CPC H01J 37/3178; H01J 37/20; H01J 37/3053; H01J 2237/24585; H01J 2237/31745; H01J 2237/31749

(57) ABSTRACT

Method and system for sample preparation includes positioning an extraneous specimen close to a target specimen in a vacuum chamber, directing a charged particle beam towards the extraneous specimen while flowing a precursor gas in the vacuum chamber, and depositing or etching on one or more surfaces of the target specimen with the assist of the precursor gas.

### CROSS-REFERENCE TO RELATED APPLICATIONS

This application claims the benefit of the filing date of U.S. Provisional Application Ser. 63/397,749 filed on Aug. 12, 2022, the disclosure of which is incorporated herein by reference in its entirety.

### FIELD OF THE INVENTION

The present description relates generally to methods and systems for specimen preparation, and more particularly, to depositing materials on a specimen using charged particle beams.

### SUMMARY

In an aspect, a specimen preparation method includes positioning a target specimen in a vacuum chamber; positioning an extraneous specimen close to the target specimen; flowing a precursor gas in the vacuum chamber; irradiating the extraneous specimen with a charged particle beam; and depositing or etching one or more surfaces of the specimen with the precursor gas. In this way, material can be deposited substantially without direct irradiation of the target specimen by the charged particle beam.

In some embodiments, flowing the precursor gas includes flowing the precursor gas towards the target specimen, where deposition or etching onto the one or more surfaces of the target specimen can be mediated by electrons generated by irradiating the extraneous specimen with the charged particle beam. Deposition of a material onto the one or more surfaces of the target specimen can include disassociating the precursor gas with the electrons.

In some embodiments, the charged particle beam is generated from a charged particle source positioned on a same side of the target specimen relative to the extraneous specimen. The charged particle beam can be an ion beam or an electron beam. Flowing a precursor gas can include flowing the precursor gas towards the extraneous specimen, and the method of the present aspect can include depositing a material on the extraneous specimen from the precursor gas while depositing the material on the one or more surfaces the target specimen. In some embodiments, at least a part of the deposition of the material on the one or more surfaces of the target specimen is deposited from the material sputtered from the deposited material on the extraneous specimen by the charged particle beam.

In some embodiments, the target specimen includes two opposing surfaces, where flowing the precursor gas includes concurrently flowing the precursor gas towards the two opposing surfaces, and where depositing a material on one or more surfaces of the target specimen can include concurrently depositing the material on the two opposing surfaces of the target specimen. Depositing the material on the two opposing surfaces of the target specimen includes depositing the material on the two opposing surfaces at a substantially equal rate. The material deposited on the two opposing surfaces can have a substantially equal thickness at a particular height of the target specimen. The extraneous specimen can have a surface, as a portion of the surface of the extraneous specimen, where positioning the extraneous specimen can include positioning the extraneous specimen so that a substantially flat surface is oriented toward the target specimen. The surface can include flat region(s), concave region(s), convex region(s), or combinations thereof. The substantially flat surface of the extraneous specimen can be oriented substantially normal to an axis along which the target specimen extends. Irradiating the extraneous specimen with a charged particle beam can include placing two imaging patterns on the substantially flat surface of the extraneous specimen, each imaging pattern on a respective side of a projection of the target specimen on the extraneous specimen, and alternatively irradiating the imaging patterns with the charged particle beam. Irradiating the extraneous specimen with the charged particle beam can include placing two imaging patterns on the substantially flat surface of the extraneous specimen, each imaging pattern on a respective side of a projection of the target specimen on the extraneous specimen, and concurrently irradiating the two imaging patterns with two charged particle beams.

In some embodiments, the method of the present aspect further includes milling through the deposited specimen to expose a cross-section of the specimen. The target specimen can be a lamella. The target specimen can be a wedge lamella. The extraneous specimen can include silicon. The extraneous specimen can have a shape of a cuboid. A material deposited on the one or more surfaces of the target specimen can include one or more of tungsten, platinum, carbon, and silicon oxide. The extraneous specimen can be irradiated with the charged particle beam at an angle of incidence equal or less than about 45 degrees. The method of the present aspect can further include milling through the deposited material to expose a region of interest of the target specimen.

In another aspect, a charged particle system includes a charged particle source for generating a charged particle beam; a vacuum chamber; a specimen holder for positioning a target specimen in the vacuum chamber; a gas injection system (GIS) for delivering at least a precursor gas into the vacuum chamber; a micro-manipulator; and a controller including a processor and a non-transitory memory for storing computer readable instructions, by executing the computer readable instructions in the processor, the charged particle system can perform operations including: positioning an extraneous specimen close to the target specimen using the micro-manipulator; introducing the precursor gas into the vacuum chamber; irradiating the extraneous specimen with the charged particle beam; and depositing on or etching from one or more surfaces of the target specimen with the precursor gas.

In some embodiments, the charged particle source and the extraneous specimens are positioned on opposite sides of the target specimen. The target specimen can be a lamella extending along a first axis, and wherein the charged particle beam irradiates the extraneous specimen in a direction substantially along the first axis. The operations can further include milling through the deposited or etched surfaces of the target specimen to expose a cross-section; and acquire an image of the cross-section. The operations can further include measuring a thickness of the specimen based on the image. The charged particle source can be an ion source. The charged particle source can be an electron source. The target specimen can be a lamella prepared in the charged particle system. The lamella can be a wedge lamella including opposing surfaces forming a wedge, where the material can be deposited concurrently on the opposing surfaces.

It should be understood that the summary above is provided to introduce in simplified form a selection of concepts that are further described in the detailed description. It is not meant to identify key or essential features of the claimed subject matter, the scope of which is defined uniquely by the claims that follow the detailed description. Furthermore, the claimed subject matter is not limited to implementations that solve any disadvantages noted above or in any part of this disclosure.

### BRIEF DESCRIPTION OF THE DRAWINGS

The foregoing aspects and many of the attendant advantages of the present disclosure will become more readily appreciated as the same become better understood by reference to the following detailed description, when taken in conjunction with the accompanying drawings.

FIG. 1 illustrates an example charged particle microscopy system.

FIG. 2 is an image of a cross-section of an encapsuled wedged lamella.

FIG. 3 is a flowchart showing a method of preparing a target specimen.

FIG. 4 shows an image of a lamella.

FIG. 5 shows an image of an extraneous specimen.

FIG. 6 shows a configuration of the extraneous specimen and the target specimen during the specimen preparation.

FIG. 7 is the configuration of FIG. 6 viewing from another angle.

FIG. 8 shows imaging patterns positioned in the configuration of FIG. 6.

FIG. 9 shows a gas injection system positioned for providing precursor gas in the vacuum chamber.

FIG. 10 shows depositions formed using the method shown in FIG. 3.

FIG. 11 is an image showing a cross-section of an encapsulated wedged lamella.

FIG. 12 and FIG. 13 are different views of an illustration showing the relative positions of the target specimen and the extraneous specimen.

In the drawings, like reference numerals refer to like parts throughout the various views unless otherwise specified. Not all instances of an element are necessarily labeled to reduce clutter in the drawings where appropriate. The drawings are not necessarily to scale, emphasis instead being placed upon illustrating the principles being described.

### DETAILED DESCRIPTION

The following description relates to systems and methods for preparing a specimen using a charged particle microscope. The prepared specimen can be further inspected or processed in the same or a different charged particle microscope. For example, the prepared specimen can be inspected using a transmission electron microscopy (TEM) system. TEM allows observers to see features having sizes on the order of nanometers. To acquire high resolution TEM images, a lamella with a thickness of a few nanometers can be required. The lamella can be obtained by milling a chunk specimen with an ion beam using, for example, a dual-beam system. In one example, the lamella can be obtained using methods disclosed in U.S. Pat. No. 8,859,998B2, by Blackwood et al., which is incorporated herein by reference for its entirety and for all purposes, wherein the lamella is prepared by thinning an inverted specimen. In some examples, the lamella can be milled into a wedged shape (i.e. wedged lamella), wherein the lamella thickness is tapered/reduced towards the bottom edge.

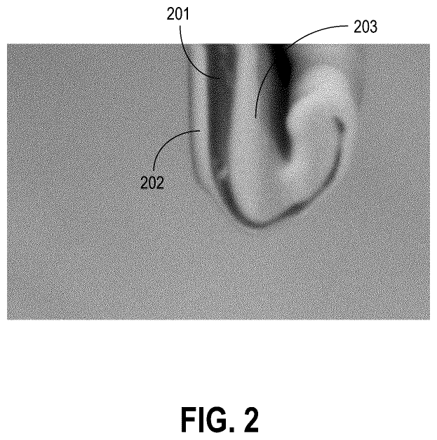

To perform metrology analysis on the lamella, such as measuring the thickness of the lamella, one or both surfaces of the lamella can be encapsulated by depositing materials to provide imaging contrast. Further, the deposited materials can provide mechanical support for further processing, such as milling, of the lamella. The material deposition can be induced by charged particle beams using a precursor gas. However, due at least in part to strain and other mechanical effects, the lamella can deform, such as curling or bending, resulting at least in part from the internal tensile or compressive stresses within the deposited layers, if the deposition on the opposing surfaces of the lamella are asymmetric. In one example, FIG. 2 is a SEM image showing the tip of a wedged lamella 201 with opposing surfaces deposited with tungsten. The tungsten layers 203 and 202 were deposited by directly irradiating the lamella surface at a tilt with the ion beam while flowing a precursor gas towards the lamella surface. The tungsten layer 203 was deposited first by irradiating the lamella surface with an ion beam. The lamella tip was curled while carbon layer 203 was deposited. Then, the carbon layer 202 was deposited by irradiating the opposing lamella surface with the ion beam.

To address the above issues, materials are deposited on a target specimen by positioning an extraneous specimen close to the target specimen, wherein the extraneous specimen is not in direct contact with the target specimen. The distance between the target specimen and the extraneous specimen is within 10 micrometers. In some examples, the distance between the target specimen and the extraneous specimen is within 100 nanometers. A precursor gas is introduced into the vacuum chamber. The extraneous specimen is then irradiated with a charged particle beam, and at least one material is deposited on one or more surfaces of the target specimen from the precursor gas. In some examples, instead of depositing a material, the one or more surfaces of the target specimen can be etched with the precursor gas while the charged particle beam being is directed towards the extraneous specimen. During the deposition or etching process, the deposited or etched surface of the target specimen cannot be directly irradiated with the charged particle beam.

In one example, the precursor gas is flown towards the extraneous specimen. Irradiating the extraneous specimen with the charged particle beam causes a primary deposition of the material on the surface of the extraneous specimen. Electrons are generated from the extraneous specimen and/or the primary deposition due to the irradiation. The deposition or etching of the target specimen can be induced by the generated electrons with the assistance of the precursor gas. The electrons can include one or more of secondary electrons, backscattered electrons, Auger electrons, inelastically scattered electrons, and elastically scattered electrons. For the target specimen positioned on the same side of the source relative to the extraneous specimen, the electrons that induce the deposition can be one or more of secondary electrons, backscattered electrons, and Auger electrons. For the target specimen positioned on the opposite side from the source relative to the extraneous specimen, the electrons that induced the deposition can be one or more of inelastically scattered electrons and elastically scattered electrons.

The precursor gas can include one or more gas species. For gas-assisted etching, the gas species can be determined based on the material of the target specimen. For example, XeF2 (Xenon difluoride) is a beam-induced etchant for SiOx (Silicon oxide). For gas-assisted deposition, the gas species can be based at least in part on the materials to be deposited on the target specimen. For example, tungsten hexacarbonyl can be used as the precursor gas for depositing tungsten. The deposition can include one or more of platinum, tungsten, carbon, silicon oxide, or other species of interest (e.g., nitrides, metals, or the like).

The charged particle beam can irradiate the extraneous specimen from the same side of the target specimen relative to the extraneous specimen. The charged particle source and the target specimen can be positioned on the same side of the extraneous specimen. The deposition or etching of the target specimen is at least partially caused by the electrons emitted from the same side of the extraneous specimen being irradiated with the charged particle beam. Alternatively, the charged particle beam can irradiate the extraneous specimen from a different side of the target specimen relative to the extraneous specimen. The deposition or etching is at least partially caused by the electrons emitted from a different side (e.g. the opposite side) of the extraneous specimen being irradiated with the charged particle beam.

In one example, the precursor gas is introduced concurrently towards one or more surfaces of the target specimen and a surface of the extraneous specimen facing the target specimen. The charged particle beam can irradiate the surface of the extraneous specimen from the same side of the target specimen relative to the extraneous specimen. The one or more surfaces of the target specimen can be concurrently deposited or etched by the gas-assisted deposition or gas-assisted etching, respectively. The deposition on the target specimen is herein also referred to as the secondary deposition.

In one example, the target specimen is a thin specimen including two opposing surfaces, such as a lamella. The two opposing surfaces can be either parallel or non-parallel to each other. For example, the two opposing surfaces are not parallel to each other, such as in a wedged lamella. The extraneous specimen can be positioned in a plane substantially normal to the thin specimen. The precursor gas can be flown toward both surfaces of the target specimen. For gas-assisted deposition, the material can be deposited concurrently on both surfaces of the thin specimen. For gas-assisted etching, both surfaces of the thin specimen can be etched concurrently.

The charged particle beam can irradiate the extraneous specimen surface in a direction substantially within the plane of the target specimen. In some examples, the extraneous specimen surface is irradiated with the charged particle beam at an angle of incidence equal or lower than 45 degrees.

The charged particle beam can be either an ion beam or an electron beam.

The extraneous specimen can include a surface facing the target specimen. Irradiating the extraneous specimen with the charged particle beam includes positioning one or more imaging patterns on the surface of the extraneous specimen and scanning the imaging patterns with the charged particle beam.

To concurrently or concurrently etch or deposit material on the two opposing surfaces of the thin specimen, the two imaging patterns on the extraneous surface of the specimen surface can be positioned on different sides of the projection of the thin specimen on the extraneous specimen surface. In one example, the charged particle beam (such as the focused ion beam) can alternatively scan each of the first and second imaging patterns. The beam parameters such as beam energy and beam profile for scanning the two imaging patterns can be the same so that the same amount of material is deposited or removed from the opposing sides. During the specimen preparation process, the two imaging patterns can be alternatively scanned for hundreds or thousands of times. In another example, the extraneous specimen can be concurrently irradiated with two charged particle beams. Each beam can irradiate or scan one imaging pattern. The two charged particle beams can be split from one charged particle beam, or alternatively generated from different sources. By concurrently depositing or etching the two opposing surfaces of the target specimen, deformation of the specimen, such as the bending and curling of a wedged lamella shown in FIG. 2, can be avoided.

In one example, the deposition/etching speed on the multiple surfaces of the target specimen can substantially be the same. In another example, the deposition/etching speed on the multiple surfaces of the target specimen can be different. The deposition speed can be controlled by adjusting the amount of precursor gas delivered towards each surface. The amount of the precursor gas delivered can be adjusted by adjusting the direction of the gas delivery direction relative to the surfaces.

In one example, the thickness of the deposited material on each of the opposing surfaces of the target specimen can be substantially the same. In particular, the material deposited on the two opposing surfaces has a same thickness at the same height of the specimen. In another example, the amount of the material removed by the etching from each of the opposing surfaces of the target specimen can be substantially the same.

In one example, the extraneous specimen is milled from silicon. The deposited material can be one or more of tungsten, carbon, and silicon oxide, among other materials.

For the gas-assisted deposition, a portion of the material that is deposited on the target specimen's surface(s) can be caused by the redeposition of the sputtered materials from the primary deposition by the charged particle beam. As such, the secondary deposition can include material sputtered from the primary deposition, as well as material from deposition induced by the electrons generated from irradiating the extraneous specimen.

In one example, the charged particle source irradiates the specimen from the same side of the target specimen relative to the extraneous specimen, while flowing the precursor gas towards both the target specimen and the extraneous specimen. Material can be concurrently deposited on or removed from the target specimen and the extraneous specimen, based on the type of precursor gas used.

In some examples, the extraneous specimen can be cleaned for preparing multiple target specimens or multiple sites of the target specimen. The deposited material on the extraneous specimen can be removed or cleaned for example via milling before re-use.

After depositing or etching the target specimen, the target specimen can be further processed. For example, the deposited specimen can be milled by milling through one or more deposited layers to expose a region of interest, such as a cross-section, of the target specimen. The cross-section can be imaged, for example using TEM, to perform metrology analysis.

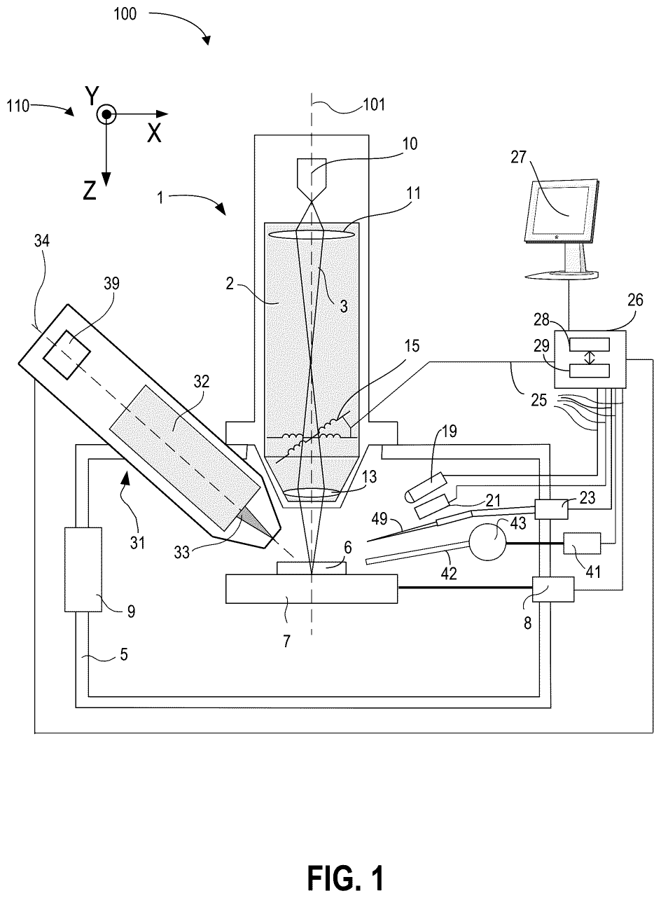

In one embodiment, the extraneous specimen and/or the target specimen can be prepared in the dual-beam microscopy system, such as the system shown in FIG. 1. The precursor gas can be delivered via a gas injection system (GIS). The extraneous specimen can be held by a micro-manipulator and positioned in the vicinity of the lamella. The lamella can be prepared using the method disclosed in U.S. Pat. No. 8,859,998B2. In some examples, the lamella can be in a wedged shape, wherein the two opposing surfaces formed a wedge, and wherein the thickness decreases along the height and towards the bottom edge of the lamella.

Turning to FIG. 1, FIG. 1 is a highly schematic depiction of an embodiment of a dual-beam charged particle microscopy (CPM) system in which the present invention can be implemented; more specifically, it shows an embodiment of a FIB-SEM. System coordinates are shown as 110. Microscope 100 comprises an electron-optical column 1, which produces a beam 3 of charged particles (in this case, an electron beam) that propagates along an electron-optical axis 101. Electron-optical axis 101 can be aligned with the Z axis of the system. The column 1 is mounted on a vacuum chamber 5, which comprises a specimen holder 7 and associated actuator(s) 8 for holding/positioning a specimen 6. Micro-manipulator 49 can be actuated by actuator 23 for manipulating a specimen/specimen, such as a small specimen extracted from specimen 6. The vacuum chamber 5 is evacuated using vacuum pumps (not depicted). Also depicted is a vacuum port 9, which can be opened to introduce/remove items (components, specimens) to/from the interior of vacuum chamber 5. Microscope 100 can comprise a plurality of such ports 9, if desired.

The column 1 comprises an electron source 10 and an illuminator 2. This illuminator 2 comprises lenses 11 and 13 to focus the electron beam 3 onto the specimen 6, and a deflection unit 15 (to perform beam steering/scanning of the beam 3). The microscope 100 further comprises a controller/computer processing apparatus 26 for controlling inter alia the deflection unit 15, lenses 11, 13, micro-manipulator 49, and detectors 19, 21, and displaying information gathered from the detectors 19, 21 on a display unit 27.

In addition to the electron column 1 described above, the microscope 100 also comprises an ion-optical column 31. This comprises an ion source 39 and an illuminator 32, and these produce/direct an ion beam 33 along an ion-optical axis 34. To facilitate easy access to the specimen, the ion axis 34 is canted relative to the electron axis 101. As hereabove described, such an ion (FIB) column 31 can, for example, be used to perform processing/machining operations on the specimen 6, such as incising, milling, etching, depositing, etc. The ion column 31 can also be used to produce imagery of the specimen 6. It should be noted that ion column 31 can be capable of generating various different species of ion at will; accordingly, references to ion beam 33 should not necessarily been seen as specifying a particular species in that beam at any given time—in other words, the beam 33 might comprise ion species A for operation A (such as milling) and ion species B for operation B (such as implanting), where species A and B can be selected from a variety of possible options. The ion source 39 can be a liquid metal ion source or a plasma ion source.

Also illustrated is a Gas Injection System (GIS) 43, which can be used to effect localized injection of precursor gases for the purposes of performing gas-assisted etching or deposition. Such gases can be stored/buffered in a reservoir 41, and can be administered through a narrow nozzle 42, so as to emerge in the vicinity of the intersection of axes 101 and 34, for example.

The detectors 19, 21 are chosen from a variety of possible detector types that can be used to examine different types of “stimulated” radiation emanating from the specimen 6 in response to irradiation by the (impinging) beam 3 and/or beam 33. Detector 19 can an X-ray detector, such as Silicon Drift Detector (SDD) or Silicon Lithium (Si(Li)) detector, for example. Detector 21 can be an electron detector in the form of a solid-state photomultiplier (SSPM) or evacuated photomultiplier tube (PMT) for example. This can be used to detect backscattered and/or secondary electrons emanating from the specimen. The skilled artisan will understand that many different types of detectors can be chosen in a set-up such as that depicted, including, for example, an annular/segmented detector. By scanning the beam 3 or beam 33 over the specimen 6, stimulated radiation—comprising, for example, X-rays, infrared/visible/ultraviolet light, secondary ions, secondary electrons (SEs) and/or backscattered electrons (BSEs)—emanates from the specimen. Since such stimulated radiation is position-sensitive (due to said scanning motion), the information obtained from the detectors 19 and 21 will also be position-dependent.

The signals from the detectors 19 and 21 pass along control lines (buses) 25, are processed by the controller 26, and displayed on display unit 27. Such processing can include operations such as combining, integrating, subtracting, false coloring, edge enhancing, and other processing known to the skilled artisan. In addition, automated recognition processes can be included in such processing. The controller includes a non-transitory memory 29 for storing computer readable instructions and a processor 28. Methods disclosed herein can be implemented by executing the computer readable instructions in the processor. For example, the controller can control the microscope to mill and image the specimen, collect data, and process the collected data for generating the 3D model of the features inside the specimen. The controller can control the microscope to mill a specimen mounted on a TEM grid, image the milled specimen, and display the image on the display. The controller can adjust the ion beam energy by adjusting one or more lenses and/or the ion source. The controller can adjust the ion beam direction relative to the specimen by adjusting either the specimen orientation and/or the optical parts in the ion column.

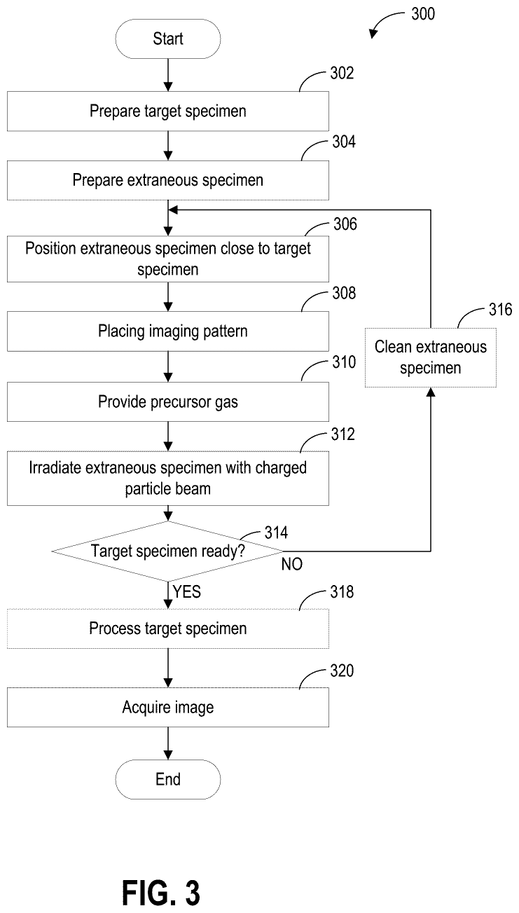

FIG. 3 shows method 300 for depositing or etching a target specimen in a charged particle microscopy system, such as the dual-beam system shown in FIG. 1. The deposition or etching is assisted with a precursor gas provided into the vacuum chamber. An extraneous specimen positioned close to the target specimen is irradiated with the charged particle beam. The disassociation of the precursor gas can be induced by the charged particle beam and/or electrons generated as a result of the charged particle beam irradiating the extraneous specimen.

At 302, the specimen is prepared. The specimen can be prepared using the same dual-beam system shown in FIG. 1. Alternatively, the specimen can be prepared in another system, and transferred into the dual-beam system. In one example, the specimen is a thin specimen with opposing surfaces. The thin specimen can be defined with a length, a thickness, and a height. The planner specimen can extend in the plan formed by the length and the height. The two opposing surfaces can or can not be parallel to each other. In another example, the thin specimen is a lamella. The lamella can have a thickness less than 100 nm. In yet another example, the lamella is a wedged lamella, wherein the wedge is formed by the two opposing surfaces intersecting at the bottom of the lamella.

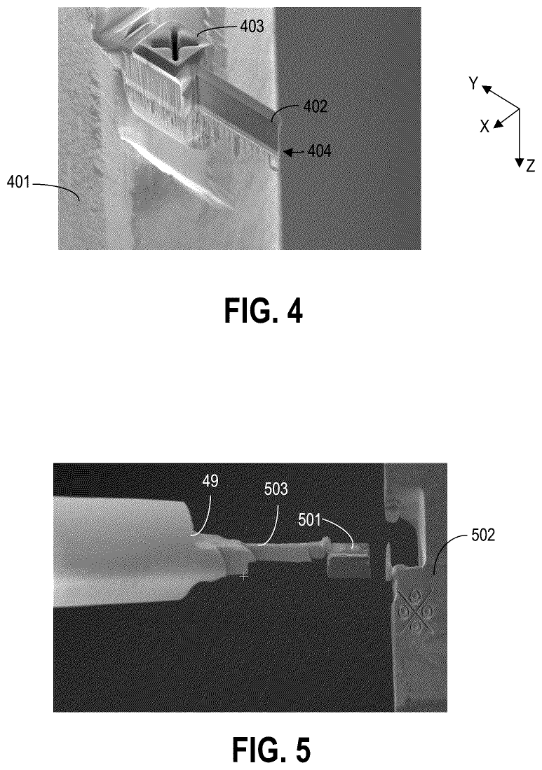

FIG. 4 is a SEM image showing an example of wedged lamella 402 attached to FIB lift-out grid 401. The wedged lamella extends along the Y-Z plane, wherein the transistor layer 404 locates close to the bottom edge of the lamella. The Y-axis corresponds to length, the X-axis corresponds to thickness, and the Z-axis corresponds to height. The wedged lamella 402, together with fiducial 403, were prepared by thinning a bulk specimen. The fiducial 403 was created by FIB milling. The wedged lamella 402 was welded to the FIB lift-out grid 401. The wedged lamella 402 was prepared using the inverted thinning method. To check the thickness of the lamella at the position of the transistor layer, the lamella around the bottom edge needed to be encapsulated so that cross-section cut can be made.

At 304, the extraneous specimen is prepared. The extraneous specimen can be prepared in the dual-beam system from a chunk specimen. In one example, the extraneous specimen can be larger in all three dimensions comparing to the specimen. In another embodiment, the extraneous specimen is larger in at least two dimensions comparing to the specimen. For example, the extraneous specimen can be larger than the specimen in length and height. The extraneous specimen can be thin in thickness so that the second electrons can emit from the surface opposite to the one that is being irradiated with the charged particle beam.

FIG. 5 shows an example of the extraneous specimen 501 prepared by milling a chunk specimen. The extraneous specimen 501 is prepared while being attached to the FIB lift-off grid 502. After the preparation, the extraneous specimen is welded to the needle 503 attached to the micro-manipulator 49. The extraneous specimen can then be separated from the FIB lift-off grid 502. The extraneous specimen can be in cuboid shape.

At 306, the target specimen is positioned in the vacuum chamber, and the extraneous specimen is positioned close to the target specimen, without directly in contact with the target specimen. In one example, the extraneous specimen should be positioned sufficiently close to the target specimen so that electrons generated from extraneous specimen can reach the specimen. In another example, the extraneous specimen should be positioned sufficiently close to the target specimen so that sputtered materials from the primary deposition on the extraneous specimen can reach the specimen. The extraneous specimen can be positioned away from the target specimen in such a way that the primary deposition on the extraneous specimen will not get in contact with the target specimen or the secondary deposition on the target specimen during the deposition process.

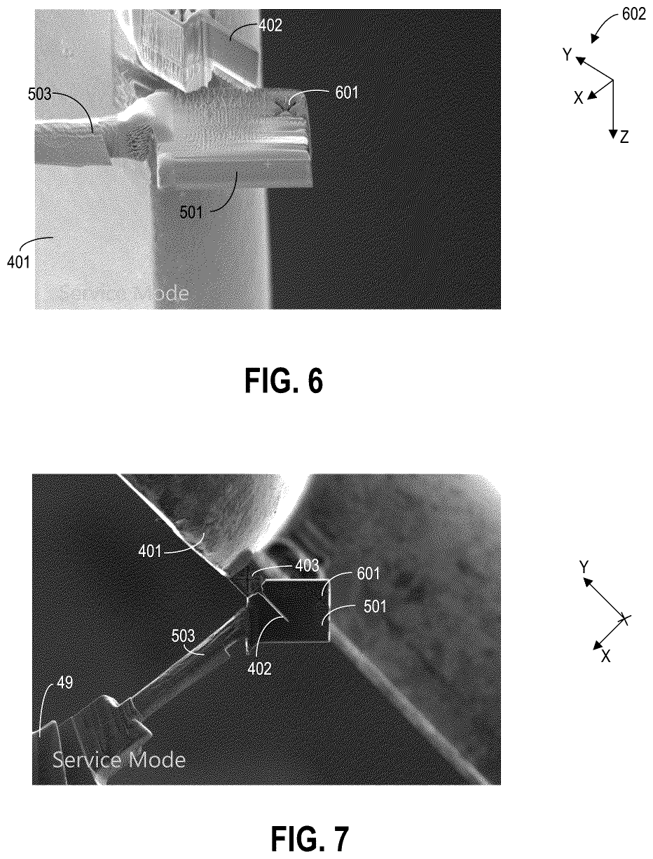

In one example, the target specimen is a thin specimen. The extraneous specimen is positioned in a plane substantially normal relative to the thin specimen. In particular, a surface of the extraneous specimen is substantially normal to the thin specimen. The surface can be part of an overall surface that is substantially flat, concave, convex, or combinations thereof. FIG. 6 shows the extraneous specimen 501 being positioned close to lamella 402. The coordinate system 602 shows the coordinates of the target specimen, defined similarly as the coordinates shown in FIG. 4. FIG. 7 is another view of the configuration shown in FIG. 6, viewing along the Z direction. In FIGS. 6-7, the lamella 402 is positioned in a plane X-Z normal to the X-Y plane wherein the flat surface of the extraneous specimen is located. The extraneous specimen position can be adjusted by operating the micro-manipulator 49 via needle 503. The fiducial 601 created on the extraneous specimen can be used to guide the positioning of the extraneous specimen. The position of lamella 402 can be adjusted by adjusting the FIB lift-out grid 401 via the specimen holder.

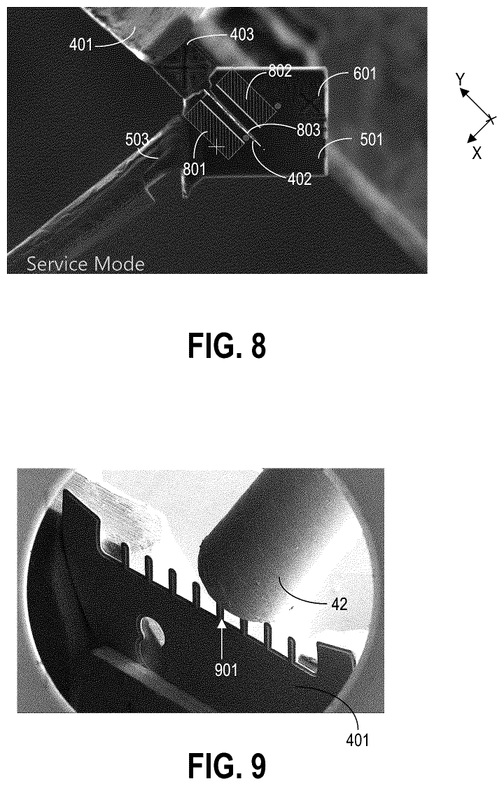

At 308, the imaging patterns are placed on the surface of the extraneous specimen. The imaging patterns define the regions that are to be irradiated with the charged particle beam. In the example of depositing or etching the opposing surfaces of a thin specimen, two imaging patterns are positioned on the extraneous specimen. As shown in FIG. 8, imaging patterns 801 and 802 were shown on the surface of extraneous specimen 501. The imaging patterns were positioned on different sides of the projection 803 of the lamella 402 on the extraneous specimen 501. The imaging patterns can be symmetric relative to the projection 803.

At 310, the precursor gas is provided in the vicinity of the target specimen and the extraneous specimen using the GIS. The precursor gas can be flown towards both or either one of the target specimen and the extraneous specimen. The precursor gas can flow in a direction substantially in the plane of the specimen (e.g. the Y-Z plane in FIGS. 6-7), so that the same amount of precursor gas is provided on each side of the thin specimen. In one example, FIG. 9 shows the GIS nozzle positioned close to the target specimen (not shown) attached to post 901 of the FIB lift-off grid 401, and flew the precursor gas towards the specimen.

At 312, the extraneous specimen is irradiated with the charged particle beam, such as the FIB beam. The charged particle beam irradiates the extraneous specimen according to the imaging patterns placed at 308. For example, the charged particle beam scans the surface regions of the extraneous specimen covered by the imaging patterns.

In the example shown in FIG. 8, wherein the imaging patterns were placed on each side of the projection 803, the ion beam can scan imaging pattern 801 and imaging pattern 802 alternatively. For example, after finishing scanning imaging pattern 801 with FIB, imaging pattern 802 is scanned. Then, imaging pattern 801 is scanned again. During each scan of a particular imaging pattern, a small amount of material is deposited onto the corresponding surface of the target specimen. By alternatively scanning the imaging patterns, the material deposition speed of the material on the opposing surfaces of the target specimen are kept substantially the same.

In another example, instead of scanning the entire imaging pattern on one side of the projection 803, the FIB can irradiate a portion of the imaging patterns on different sides of the projection 803. For example, after a first portion of imaging pattern 801 is scanned, the FIB is moved to scan a first portion of imaging pattern 802. Then, a second portion of the imaging pattern 801 is scanned. As such, after multiple scans, the entire imaging patterns 801 and 802 are irradiated with FIB.

In yet another example, if the charged particle microscopy system can generate multiple charged particle beams, the imaging patterns 801 and 802 can be irradiated concurrently. The multiple charged particle beams can be generated by splitting a charged particle beam originated from a single source, or be generated by multiple sources.

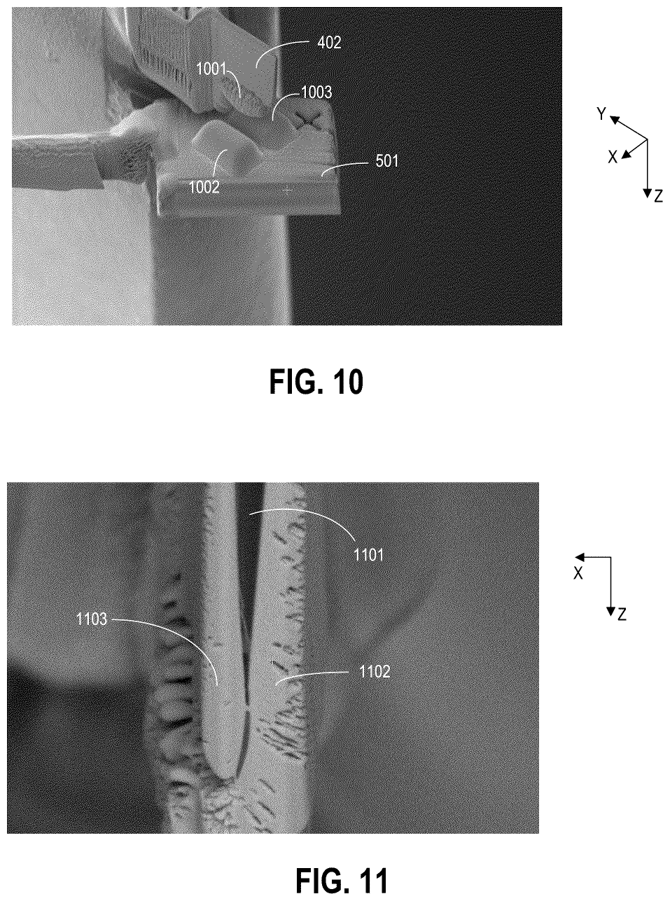

FIG. 10 shows tungsten deposited on the lamella 402 and extraneous specimen 501 after alternatively irradiating the imaging patterns 801 and 802 shown in FIG. 8 with a FIB beam while flowing tungsten hexacarbonyl towards the target and the extraneous specimens. The amount of material deposited on each side of the lamella 402 was substantially the same. Deposition 1002 and deposition 1003 were primary depositions caused by disassociation of the precursor gas induced by the FIB. Deposition 1001 was the secondary deposition on the target specimen.

Deposition on the target specimen (i.e. the secondary deposition) can due to two mechanisms. For the first mechanism, deposition is caused by precursor gas disassociation induced by electrons. The electrons are generated from the charged particle beam irradiating the extraneous specimen and/or the primary deposition on the extraneous specimen. For the second mechanism, the deposition is caused by redeposition of materials sputtered away from the primary deposition. The proportion of material deposited from the two mechanisms can be adjusted by adjusting the direction of the gas flow. For example, if the target specimen is oriented such that one face is shadowed from the gas flux, but the extraneous specimen is not, the secondary deposition is mainly caused by the second mechanism.

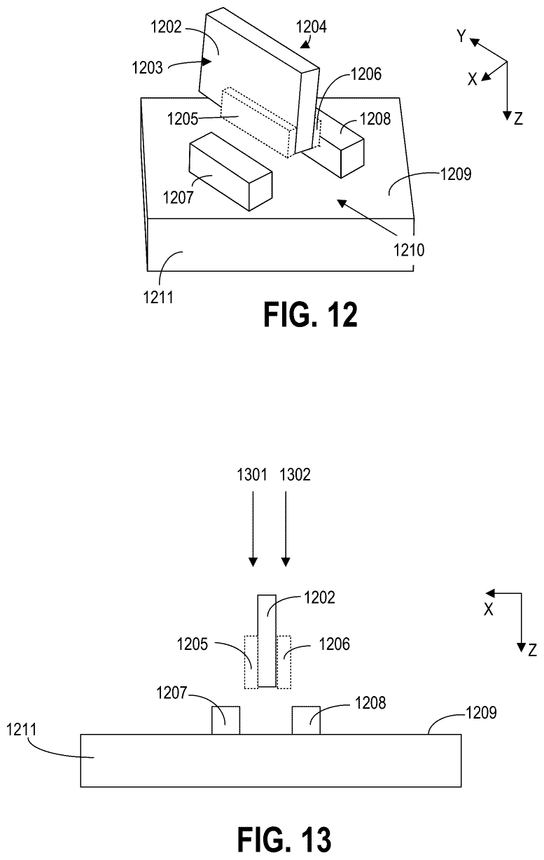

FIGS. 12-13 are illustrations showing the configuration for depositing materials on both sides of the target specimen. In particular, they show the relative positions of the target specimen 1204 and the extraneous specimen 1211 with respect to the charged particle beam and the precursor gas flow 1210. The target specimen can be a lamella. The target specimen in positioned in plane Y-Z, which is the same plane that the target specimen extends. The extraneous specimen is positioned close to the target specimen but not in contact with the target specimen. Herein, the extraneous specimen is substantially normal to the target specimen. The gas flow 1210 is in a direction substantially in the same plane as the target specimen 1204. As such, the same amount of the precursor gas is provided concurrently towards each surface of the target specimen 1204. Meanwhile, the precursor gas is flown towards the surface 1209 of the extraneous specimen 1211. Primary depositions 1207 and 1208 are formed on the surface 1209 of the extraneous specimen responsive to the scan of the charged particle beam according to the imaging patterns. The precursor gas adsorbed on the surface 1209 of the extraneous specimen is disassociated by the charged particle beam. The charged particle beam can alternatively scan the imaging patterns as indicated by arrows 1301 and 1302. Secondary depositions 1205 and 1206 are formed on the opposing surfaces of the target specimen. Secondary deposition 1205 is formed on one of the opposing surfaces 1203 of the target specimen 1204.

At 314, method 300 checks whether the target specimen preparation has been finished. The preparation can be either gas-assisted etching or gas-assisted deposition. If the target specimen preparation has not finished, such as more etching or deposition needs to be done, method 300 moves to 316 to clean the extraneous specimen. Otherwise, method 300 proceeds to 318.

At 316, the extraneous specimen can optionally be cleaned by removing the primary deposition. The primary deposition can be removed by the charged particle beam such as the ion beam. In some examples, instead of cleaning the extraneous specimen, another part of the extraneous specimen can be used for the subsequent etching or deposition. For example, another surface of the extraneous specimen can be used for the subsequent target specimen preparation.

At 318, the target specimen can optionally be processed for further imaging and/or metrology analysis. In one example, the target specimen is processed by milling through both one or more of the deposited or etched surfaces of the target specimen. As such, a cross-section of the target specimen can be exposed.

At 320, images of the target specimen are acquired. For example, a cross-section of the exposed target specimen is imaged. FIG. 11 shows SEM image of a cross-section of a wedged lamella 1101 being deposited with tungsten layers 1102 and 1103 on the opposing surfaces. The deposition was done with the method described herein. The cross-section was created by FIB milling through the deposited carbon layers as well as the wedged lamella. The deposited layers provided imaging contrast to better visualize the wedged lamella. Further, the mechanical support provided by the deposited layers prevented sample deformation during the FIB milling. Based on the SEM image, metrology analysis, such as the thickness of the wedged lamella, can be performed.

In this way, multiple surfaces of the sample, such as the opposing surfaces of a thin target specimen, can be etched or deposited concurrently. The integrity and shape of the target specimen is preserved during the specimen preparation procedures.

The technical effect of positioning the extraneous specimen close to the target specimen is for indirectly depositing or etching one or more surfaces of the target specimen, wherein the one or more surfaces of the target specimen are not directly irradiated by the charged particle beam. The technical effect of positioning a lamella substantially normal to a surface of the extraneous specimen and irradiating the extraneous specimen according to two imaging patterns positioned on different sides of the projection of the target specimen on the surface of the extraneous specimen is to concurrently deposit or etch the two surfaces of the lamella. Further, the amount of the material deposited on or the etched from of the two surfaces can be similar so that the lamella does not deform.

In the preceding description, various embodiments have been described. For purposes of explanation, specific configurations and details have been set forth to provide a thorough understanding of the embodiments. However, it will also be apparent to one skilled in the art that the embodiments may be practiced without the specific details. Furthermore, well-known features may have been omitted or simplified in order not to obscure the embodiment being described. While example embodiments described herein center on charged particle beam systems, and focused ion beam and/or focused electron beam systems in particular, these are meant as non-limiting, illustrative embodiments. Embodiments of the present disclosure are not limited to such embodiments, but rather are intended to address charged particle instrument systems for which a wide array of material samples can be prepared for analysis to determine chemical, biological, physical, structural, or other properties, among other aspects, including but not limited to chemical structure, trace element composition, or the like.

Some embodiments of the present disclosure include a system including one or more data processors and/or logic circuits. In some embodiments, the system includes a non-transitory computer readable storage medium containing instructions which, when executed on the one or more data processors and/or logic circuits, cause the one or more data processors and/or logic circuits to perform part or all of one or more methods and/or part or all of one or more processes and workflows disclosed herein. Some embodiments of the present disclosure include a computer-program product tangibly embodied in non-transitory machine-readable storage media, including instructions configured to cause one or more data processors and/or logic circuits to perform part or all of one or more methods and/or part or all of one or more processes disclosed herein.

The terms and expressions which have been employed are used as terms of description and not of limitation, and there is no intention in the use of such terms and expressions of excluding any equivalents of the features shown and described or portions thereof, but it is recognized that various modifications are possible within the scope of the claims. Thus, it should be understood that although the present disclosure includes specific embodiments and optional features, modification and variation of the concepts herein disclosed may be resorted to by those skilled in the art, and that such modifications and variations are considered to be within the scope of the appended claims.

Where terms are used without explicit definition, it is understood that the ordinary meaning of the word is intended, unless a term carries a special and/or specific meaning in the field of charged particle microscopy systems or other relevant fields. The terms “about” or “substantially” are used to indicate a deviation from the stated property within which the deviation has little to no influence of the corresponding function, property, or attribute of the structure being described. In an illustrated example, where a dimensional parameter is described as “substantially equal” to another dimensional parameter, the term “substantially” is intended to reflect that the two parameters being compared can be unequal within a tolerable limit, such as a fabrication tolerance or a confidence interval inherent to the operation of the system. Similarly, where a geometric parameter, such as an alignment or angular orientation, is described as “about” normal, “substantially” normal, or “substantially” parallel, or the like, the terms “about” or “substantially” are intended to reflect that the alignment or angular orientation can be different from the exact stated condition (e.g., not exactly normal) within a tolerable limit. For numerical values, such as diameters, lengths, widths, or the like, the term “about” can be understood to describe a deviation from the stated value of up to ±10%. For example, a dimension of “about 10 mm” can describe a dimension from 9 mm to 11 mm.

The description provides exemplary embodiments, and is not intended to limit the scope, applicability or configuration of the disclosure. Rather, the ensuing description of the exemplary embodiments will provide those skilled in the art with an enabling description for implementing various embodiments. It is understood that various changes may be made in the function and arrangement of elements without departing from the spirit and scope as set forth in the appended claims. Specific details are given in the description to provide a thorough understanding of the embodiments. However, it will be understood that the embodiments may be practiced without these specific details. For example, specific system components, systems, processes, and other elements of the present disclosure may be shown in schematic diagram form or omitted from illustrations in order not to obscure the embodiments in unnecessary detail. In other instances, well-known circuits, processes, components, structures, and/or techniques may be shown without unnecessary detail.

What is claimed is:

1. A method for preparing a target specimen, comprising:
positioning the target specimen in a vacuum chamber;
positioning an extraneous specimen close to the target specimen;
flowing a precursor gas in the vacuum chamber;
irradiating the extraneous specimen with a charged particle beam; and
depositing or etching on one or more surfaces of the target specimen with the precursor gas.

2. The method of claim 1, wherein flowing a precursor gas includes flowing the precursor gas towards the target specimen, and wherein deposition or etching onto the one or more surfaces of the target specimen is mediated by secondary electrons generated by irradiating the extraneous specimen with the charged particle beam.

3. The method of claim 2, wherein deposition of a material onto the one or more surfaces of the target specimen comprises disassociating the precursor gas with the electrons.

4. The method of claim 1, wherein flowing a precursor gas comprises flowing the precursor gas towards the extraneous specimen, and the method further comprises depositing a material on the extraneous specimen from the precursor gas while depositing the material on the one or more surfaces the target specimen.

5. The method of claim 4, wherein at least a portion of the material on the one or more surfaces of the target specimen is deposited from the material sputtered from the deposited material on the extraneous specimen by the charged particle beam.

6. The method of claim 1, wherein the target specimen includes two opposing surfaces, and wherein flowing a precursor gas includes concurrently flowing the precursor gas towards the two opposing surfaces, and wherein depositing a material on one or more surfaces of the target specimen includes concurrently depositing the material on the two opposing surfaces of the target specimen.

7. The method of claim 6, wherein the material deposited on the two opposing surfaces has a substantially equal thickness at a given height of the target specimen.

8. The method of claim 6, wherein the extraneous specimen includes a surface, and positioning the extraneous specimen includes positioning the extraneous specimen so that the surface is facing the target specimen.

9. The method of claim 8, wherein irradiating the extraneous specimen with the charged particle beam includes placing two imaging patterns on the substantially flat surface of the extraneous specimen, each imaging pattern on a different side of a projection of the target specimen on the extraneous specimen, and alternatively irradiating the imaging patterns with the charged particle beam.

10. The method of claim 1, wherein the extraneous specimen includes silicon.

11. The method of claim 1, wherein the extraneous specimen is irradiated with the charged particle beam at an angle of incidence equal or less than 45 degrees.

12. A charged particle system, comprising:
a charged particle source for generating a charged particle beam;
a vacuum chamber;
a specimen holder for positioning a target specimen in the vacuum chamber;
a gas injection system (GIS) for delivering at least a precursor gas into the vacuum chamber;
a micro-manipulator; and
a controller including a processor and a non-transitory memory for storing computer readable instructions, by executing the computer readable instructions in the processor, the charged particle system is configured to perform operations comprising:
positioning an extraneous specimen close to the target specimen using the micro-manipulator;
flowing the precursor gas;
irradiating the extraneous specimen with the charged particle beam; and
depositing on or etching from one or more surfaces of the target specimen with the precursor gas.

13. The charged particle system of claim 12, wherein the charged particle source and the extraneous specimens are positioned on opposite sides of the target specimen.

14. The charged particle system of claim 13, wherein the target specimen is a lamella extending along a first axis, and wherein the charged particle beam irradiates the extraneous specimen in a direction substantially along the first axis.

15. The charged particle system of claim 12, wherein the operations further comprise:
milling through at least part of the target specimen to expose a cross-section; and
acquiring an image of the cross-section.

16. The charged particle system of claim 12, wherein the operations further comprise measuring a thickness of the specimen based on the image.

17. The charged particle system of claim 12, wherein the charged particle source is an ion source.

18. The charged particle system of claim 12, wherein the target specimen is a lamella prepared in the charged particle system.

19. The charged particle system of claim 18, wherein the lamella is a wedge lamella including opposing surfaces forming a wedge.

20. The charged particle system of claim 12, wherein deposition on the one or more surfaces of the target specimen comprises disassociating the precursor gas with electrons generated by irradiation of the extraneous specimen.
